(19) United States
(12) Patent Application Publication
(10) Pub. No.: US 2024/0361872 A1
(43) Pub. Date: Oct. 31, 2024

(54) DISPLAY DEVICE

(71) Applicant: SHARP KABUSHIKI KAISHA, Sakai City, Osaka (JP)

(72) Inventors: JEAN MUGIRANEZA, Sakai City, Osaka (JP); YASUHIRO SUGITA, Sakai City, Osaka (JP)

(21) Appl. No.: 18/571,914

(22) PCT Filed: Jun. 22, 2021
(86) PCT No.: PCT/JP2021/023671

§ 371 Date: Dec. 19, 2023

(51) Int. Cl. G06F 3/044; G02F 1/1333; H10K 59/40; H10K 59/80; H10K 102/00

(52) U.S. Cl. CPC G06F 3/0447; G02F 1/13338; H10K 59/40; H10K 59/8794; G06F 2203/04102; H10K 2102/311

(57) ABSTRACT

A display device includes a touch panel layer configured to detect a touch on a display surface, and a pressure sensor layer configured to detect a pressure applied to the display surface, the pressure sensor layer includes a transmission electrode, a reception electrode arranged side by side in a direction along the display surface relative to the transmission electrode, and an elastic layer configured to be elastically deformed according to the pressure applied to the display surface, and the elastic layer has a thickness equal to or less than 50 μm and has a longitudinal elastic modulus less than 0.05 MPa.

### TECHNICAL FIELD

The disclosure relates to a display device including a pressure sensor configured to detect a pressure applied to a display surface.

### BACKGROUND ART

Typically, display devices each of which includes a pressure sensor under an Organic Light Emitting Diode (OLED) light-emitting layer have been known (PTL 1 and PTL 2). Such a pressure sensor includes an elastic layer that is elastically deformed according to a pressure applied to a display surface of the display device, and a transmission electrode and a reception electrode for detecting a change in mutual capacitance according to elastic deformation of the elastic layer.

### CITATION LIST

### Patent Literature

PTL 1: U.S. Pat. No. 10,289,225
PTL 2: US 2019/0196641 A

### SUMMARY

### Technical Problem

An elastic layer of a pressure sensor mounted in a display device including a bendable OLED light-emitting layer needs to be elastically deformed so that a mutual capacitance sufficiently changes according to a pressure applied to a display surface, and needs to be formed to be sufficiently thin so that the OLED light-emitting layer can be bent. It is an object of an aspect of the disclosure to provide a display device including a pressure sensor that can be suitably mounted in a bendable display device.

### Solution to Problem

In order to solve the above-described problem, a display device according to an aspect of the disclosure includes a touch sensor configured to detect a touch on a display surface, and a pressure sensor configured to detect a pressure applied to the display surface, wherein the pressure sensor includes a transmission electrode, a reception electrode arranged side by side in a direction along the display surface relative to the transmission electrode, and an elastic layer configured to be elastically deformed according to the pressure applied to the display surface, and the elastic layer has a thickness equal to or less than 50 μm and has a longitudinal elastic modulus less than 0.05 MPa.

### Advantageous Effects of Disclosure

According to the aspect of the disclosure, a display device including a pressure sensor that can be suitably mounted in a bendable display device can be achieved.

### BRIEF DESCRIPTION OF DRAWINGS

FIG. 1 is a cross-sectional view of a display device according to an embodiment.

FIG. 2 is a cross-sectional view of a pressure sensor layer provided in the display device.

FIG. 3 is a cross-sectional view for describing an operation of the pressure sensor layer.

FIG. 4 is a plan view of transmission electrodes and reception electrodes provided in the pressure sensor layer.

FIG. 5 is a schematic view for describing the operation of the pressure sensor layer.

FIG. 6 is a schematic view for describing an operation of an elastic layer provided in the pressure sensor layer.

FIG. 7 is a schematic view for describing a detection principle of a pressure at the pressure sensor layer.

FIG. 8 is a plan view illustrating a step of forming the transmission electrodes and the reception electrodes.

FIG. 9 is another plan view illustrating a step of forming the transmission electrodes and the reception electrodes.

FIG. 10 is still another plan view illustrating a step of forming the transmission electrodes and the reception electrodes.

FIG. 11 is a plan view of transmission electrodes and reception electrodes according to a modified example.

FIG. 12 is a plan view of transmission electrodes and reception electrodes according to another modified example.

### DESCRIPTION OF EMBODIMENTS

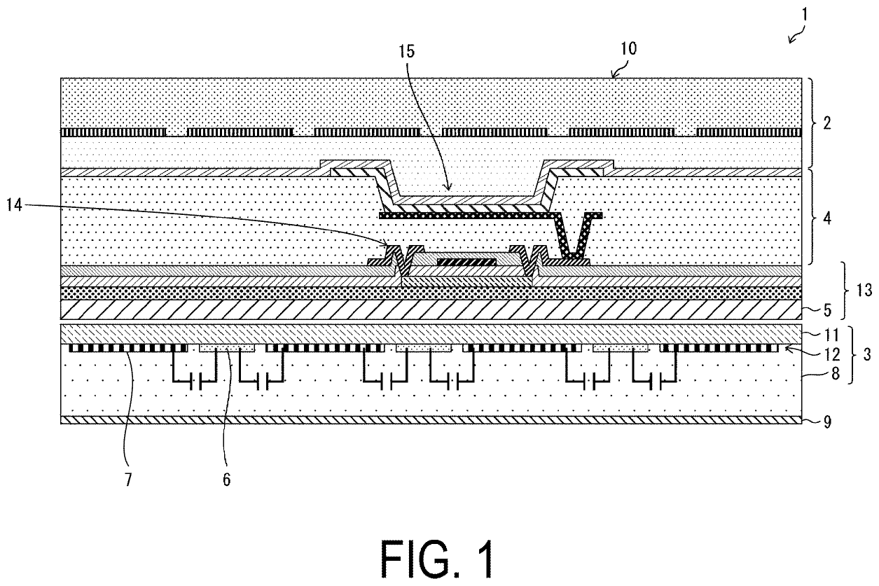

FIG. 1 is a cross-sectional view of a display device 1 according to an embodiment.

The display device 1 includes a light-emitting layer 4 configured to emit light toward a display surface 10, a touch panel layer 2 (touch sensor) formed on the light-emitting layer 4, the touch panel layer 2 being configured to detect a touch on the display surface 10, and a pressure sensor layer 3 configured to detect a pressure acting on the display surface 10.

The pressure sensor layer 3 is disposed on a side of the light-emitting layer 4 opposite to the display surface 10. The pressure sensor layer 3 includes a pressure sensor substrate 11, a pressure electrode layer 12 arranged on the side opposite to the light-emitting layer 4 of the pressure sensor substrate 11, and an elastic layer 8 configured to be elastically deformed according to a pressure acting on the display surface 10. The pressure electrode layer 12 includes a transmission electrode 6 and a reception electrode 7 arranged side by side in a direction along the display surface 10 relative to the transmission electrode 6.

The light-emitting layer 4 includes an OLED 15 (self-light-emitting element).

The display device 1 further includes a backplane 13 formed between the light-emitting layer 4 and the pressure sensor layer 3. The backplane 13 includes a Thin Film Transistor (TFT) substrate 5 (substrate) disposed between the light-emitting layer 4 and the pressure sensor layer 3 and having elasticity, and a TFT 14 formed on the TFT substrate 5 to control an operation of the OLED 15. The TFT substrate 5 is preferably constituted by a resin substrate.

The elastic layer 8 has a thickness equal to or less than 50 μm and has a Young's modulus (longitudinal elastic modulus) less than 0.05 MPa (megapascals).

The elastic layer 8 preferably includes at least one material selected from an acrylic material, a silicon-based material, and an olefinic material, and is particularly preferably made of a silicon-based material.

The display device 1 further includes a ground electrode 9 disposed on a side of the pressure sensor layer 3 opposite to the display surface 10 to dissipate heat generated from the OLED 15. The ground electrode 9 may be made of metal having flexibility.

Note that the light-emitting layer 4 may include a liquid crystal display element instead of the OLED 15.

In this way, the pressure sensor layer 3 is disposed below the TFT substrate 5 and detects a plurality of touch pressures on the display surface 10 above the OLED 15. Additionally, the elastic layer 8 that is elastically deformed in response to a pressure applied to the display surface 10 has adhesiveness, and is interposed between the pressure electrode layer 12 and the ground electrode 9.

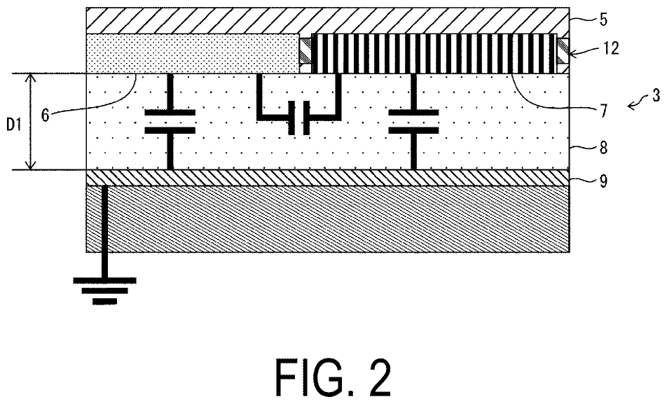

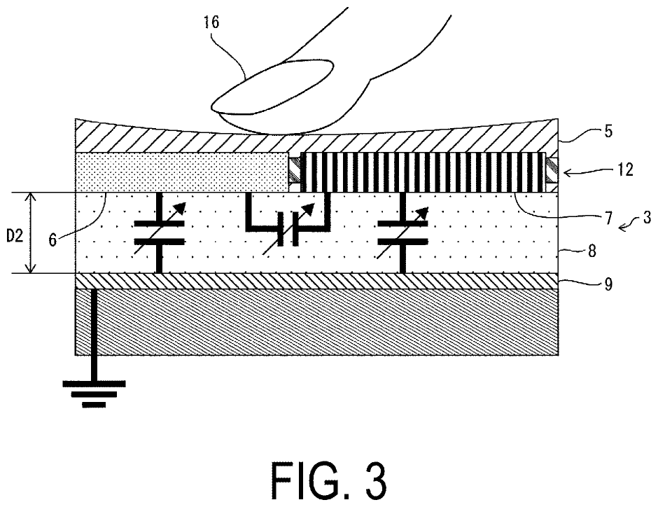

FIG. 2 is a cross-sectional view of the pressure sensor layer 3 provided to the display device 1. FIG. 3 is a cross-sectional view for describing an operation of the pressure sensor layer 3. Constituent elements similar to the constituent elements described above are given the same reference numerals, and detailed descriptions thereof are not repeated. Note that for ease of understanding, the touch panel layer 2, the light-emitting layer 4, and the backplane 13 are partially omitted in FIG. 2 and FIG. 3.

When a pressure acts on the display surface 10 above the OLED 15 with a finger 16, the pressure acting on the display surface 10 is transmitted to the TFT substrate 5 having elasticity through the touch panel layer 2 and the light-emitting layer 4. Then, the TFT substrate 5 is elastically deformed, the pressure reaches the elastic layer 8, and the elastic layer 8 is elastically deformed. This changes a distance of the pressure electrode layer 12 from the ground electrode 9 changes from a distance D1 to a distance D2, which changes a mutual capacitance between the transmission electrode 6 and the reception electrode 7. By detecting the change in the mutual capacitance, the pressure acting on the display surface 10 is detected.

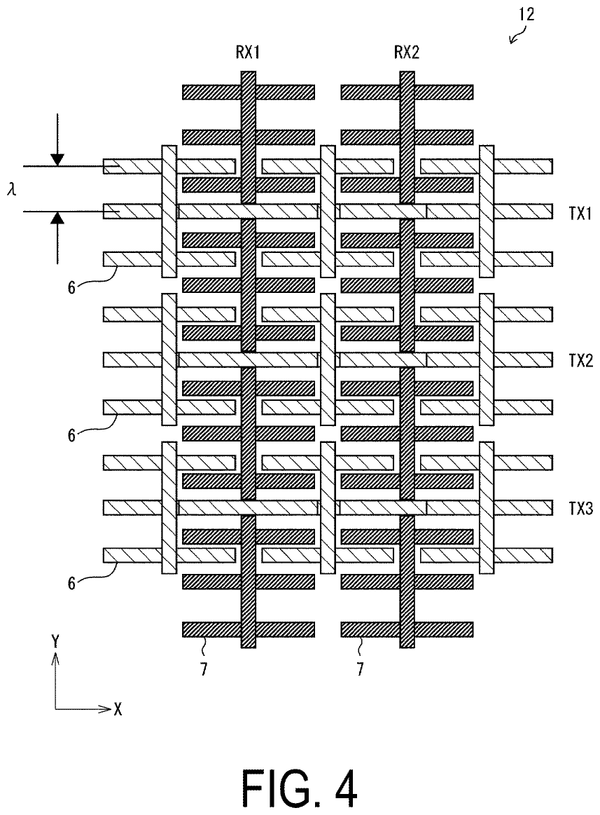

FIG. 4 is a plan view of the transmission electrodes 6 and the reception electrodes 7 provided in the pressure sensor layer 3. Constituent elements similar to the constituent elements described above are given the same reference numerals, and detailed descriptions thereof are not repeated.

As illustrated in FIG. 4, the pressure electrode layer 12 of the pressure sensor layer 3 includes a plurality of transmission electrodes 6 and a plurality of reception electrodes 7 that are formed in comb shapes having a pitch λ less than 500 μm and that are engaged with each other on an identical plane. In the example illustrated in FIG. 4, a configuration is illustrated in which three transmission electrodes 6 having the comb shape and extending in an X direction and two reception electrodes 7 having the comb shape and extending in a Y direction are engaged with each other. In this way, the reception electrodes 7 are arranged side by side in a direction along the display surface 10 relative to the transmission electrodes 6.

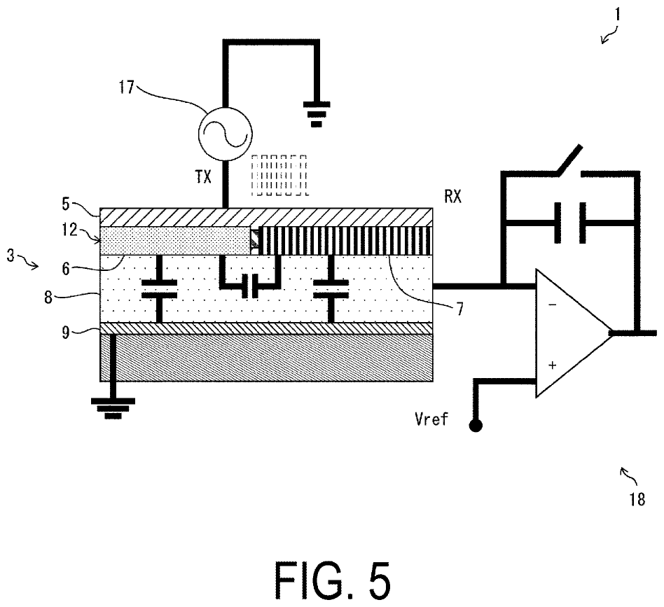

FIG. 5 is a schematic view for describing the operation of the pressure sensor layer 3. Constituent elements similar to the constituent elements described above are given the same reference numerals, and detailed descriptions thereof are not repeated.

The display device 1 further includes a signal generator 17 that generates a drive signal and then, supplies the generated drive signal to the transmission electrode 6, and a sense amplifier 18 that reads a capacitance signal based on the mutual capacitance between the transmission electrode 6 and the reception electrode 7 from the reception electrode 7.

When a pressure acts on the display surface 10, the mutual capacitance between the transmission electrode 6 and the reception electrode 7 or a mutual capacitance between each of the transmission electrode 6 and the reception electrode 7 and the ground electrode 9 changes. Then, when the drive signal is supplied from the signal generator 17 to the transmission electrode 6, the capacitance signal based on the mutual capacitance between the transmission electrode 6 and the reception electrode 7 is read from the reception electrode 7 by the sense amplifier 18. Thus, the pressure acting on the display surface 10 is detected based on the capacitance signal representing a change in the mutual capacitance between the transmission electrode 6 and the reception electrode 7 or a change in the mutual capacitance between each of the transmission electrode 6 and the reception electrode 7 and the ground electrode 9.

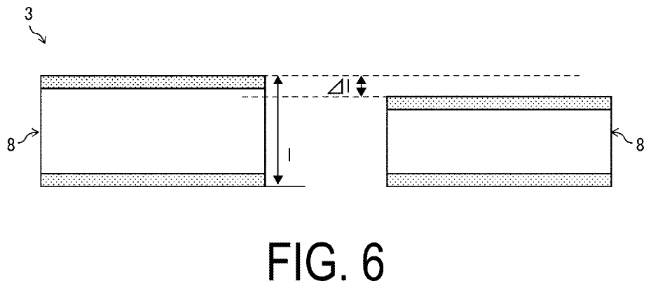

FIG. 6 is a schematic view for describing an operation of the elastic layer 8 provided in the pressure sensor layer 3. Constituent elements similar to the constituent elements described above are given the same reference numerals, and detailed descriptions thereof are not repeated.

For a known electrostatic capacitive touch sensor, a recommended detectable change in electrostatic capacitance is AC/C of 10%. According to American National Standards Institute (ANSI)/Human Factors and Ergonomics Society (HFES) (https://www.hfes.org/publications/other-publications/ansihfes-100-2007-human-factors-engineering-of-computer-workstations), a force acting on a keyboard with a human finger is between 25 gF and 150 gF (equal to 1.5 N) in consideration of an area of a human fingertip of 1.5 cm².

In a case where
C is a mutual capacitance between the transmission electrode 6 and the reception electrode 7,
ΔC is a change in the mutual capacitance,
l is a thickness of the elastic layer 8,
Δl is a change in the thickness,
ε is a change rate of the thickness,
Y is a Young's modulus,
σ is a pressure acting on the display surface 10,
F is a force acting on the display surface 10, and
A is an area of the display surface 10,
by using the following Expression (1) and Expression (2):

$$[ Expression 1 ]$$

$$\frac{Δ C}{C} = \frac{Δ l}{l} \qquad Math . 1$$

$$[ Expression 2 ]$$

$$Y = \frac{σ}{ε} , \qquad Math . 2$$

$$σ = \frac{F}{A} ,$$

$$ε = \frac{Δ l}{l}$$

and using the following Expression (3):

$$[ Expression 3 ]$$

$$>> Y = \frac{F}{A \times ε} \approx \frac{1.5}{1.5 \times {10}^{- 4}} \times \frac{100}{10} = 1 {0}^{5} Pa = 0.1 Mpa , \qquad Math . 3$$

when an elasticity required for the elastic layer 8 in order to detect a pressure σ acting on the display surface 10 is considered, the Young's modulus of the elastic layer 8 is preferably less than 0.05 MPa.

A detection sensitivity of the pressure acting on the display surface 10 by the pressure sensor layer 3 was examined. As shown in Table 1 below, in a case where a pressure of a fingertip was 0.25 N per 1 cm², sufficient capacitance signals were not obtained from the reception electrodes 7 when the Young's moduli of the elastic layer 8 were 0.2 Mpa, 0.15 Mpa, and 0.1 Mpa, and sufficient capacitance signals were obtained from the reception electrodes 7 when the Young's moduli of the elastic layer 8 were 0.05 Mpa and 0.04 Mpa.

Moreover, when the pressure of the fingertip was 0.5 N, sufficient capacitance signals were not obtained when the Young's moduli were 0.2 Mpa and 0.15 Mpa, and sufficient capacitance signals were obtained when the Young's moduli were 0.1 Mpa, 0.05 Mpa, and 0.04 Mpa. In addition, when the pressure of the fingertip was IN, sufficient capacitance signals were not obtained when the Young's moduli were 0.2 Mpa and 0.15 Mpa, and sufficient capacitance signals were obtained when the Young's moduli were 0.1 Mpa, 0.05 Mpa, and 0.04 Mpa.

TABLE 1

| Pressure (N) per | Young's modulus (MPa) of Elastic layer 8 | | | | |
|---|---|---|---|---|---|
| 1 cm² of fingertip | 0.2 Mpa | 0.15 Mpa | 0.1 Mpa | 0.05 Mpa | 0.04 Mpa |
| 0.25N | × | × | × | ✓ | ✓ |
| 0.5N | × | × | ✓ | ✓ | ✓ |
| 1N | × | × | ✓ | ✓ | ✓ |

Relationships between the thicknesses of the elastic layer 8 and the mechanical reliability for bending operation of the display device 1 are shown in Table 2 below.

TABLE 2

| | | | | |
|---|---|---|---|---|
| Thickness of elastic layer 8 | 200 | 100 | 50 | 25 |
| The number of bending | 10000 | 15000 | 50000 | >150000 |
| operations (radius: 1 to 5 mm) | | | | |

When the thickness of the elastic layer 8 was 200 μm, the mechanical reliability for bending operation of the display device 1 was confirmed up to 10000 times. When the thickness of the elastic layer 8 was reduced to 100 μm, the reliability for bending operation was confirmed up to 15000 times. When the thickness of the elastic layer 8 was reduced to 50 μm, the reliability for bending operation was increased to 50000 times. When the thickness of the elastic layer 8 was reduced to 25 μm, the reliability for bending operation was increased to nearly 150000 times.

As described above, when the thickness of the elastic layer 8 is set to be equal to or less than 50 μm, durability against the number of times of bending equal to or more than 500 million times corresponding to a use period of the display device 1 can be obtained.

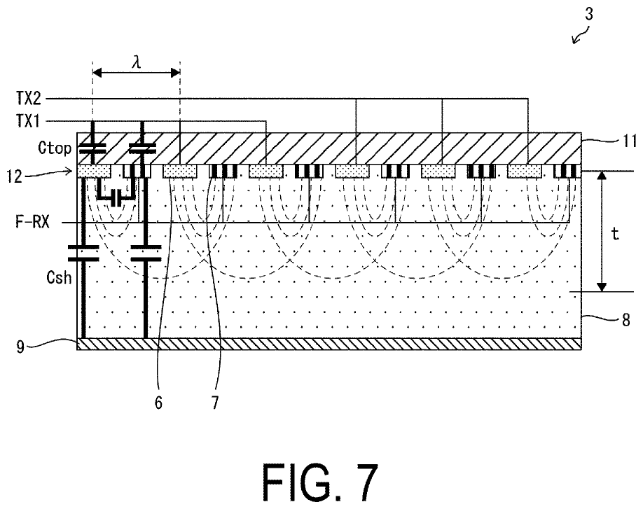

FIG. 7 is a schematic view for describing a detection principle of a pressure by the pressure sensor layer 3. Constituent elements similar to the constituent elements described above are given the same reference numerals, and detailed descriptions thereof are not repeated.

The detection principle of the pressure acting on the display surface 10 of the display device 1 will be described.

In a case where ΔCₜₒₚ is a change in electrostatic capacitance between the pressure electrode layer 12 and the display surface 10,
ΔCₛₕ is a change in electrostatic capacitance between the pressure electrode layer 12 and the ground electrode 9,
ΔCₙ is a change in electrostatic capacitance between the transmission electrode 6 and the reception electrode 7,
ΔCₜₒₜ is a total change in electrostatic capacitance, and
t is a penetration depth indicating a depth at which an electric field between the transmission electrode 6 and the reception electrode 7 penetrates into the elastic layer 8,
ΔCₜₒₜ is expressed by the following Expression (4) as the sum of ΔCₛₕ, ΔCₜₒₚ, and ΔCₙ.

$$[ Expression 4 ]$$

$$Δ {C}_{tot} = Δ {C}_{sh} + Δ {C}_{top} + Δ {C}_{n} \qquad Math . 4$$

Assuming that the change in electrostatic capacitance ΔCₜₒₚ between the pressure electrode layer 12 and the display surface 10 does not change while the pressure are acting on the display surface 10, ΔCₜₒₜ is expressed by the following Expression (5) at a position shallower than the penetration depth t. Additionally, at a position deeper than the penetration depth t, the change in electrostatic capacitance ΔCₙ between the transmission electrode 6 and the reception electrode 7 comes to have a negligible size, and ΔCₜₒₜ is expressed by the following Expression (6).

$$[ Expression 5 ]$$

$$Δ {C}_{tot} = {ΔC}_{sh} + Δ {C}_{n} \qquad Math . 5$$

$$[ Expression 6 ]$$

$$Δ {C}_{tot} = Δ {C}_{sh} \qquad Math . 6$$

As described above, according to Expression (5) and Expression (6), the total change in electrostatic capacitance ΔCₜₒₜ is larger at a position shallower than the penetration depth t than at a position deeper than the penetration depth t. This enhances the detection sensitivity of the pressure acting on the display surface 10 at a position shallower than the penetration depth t.

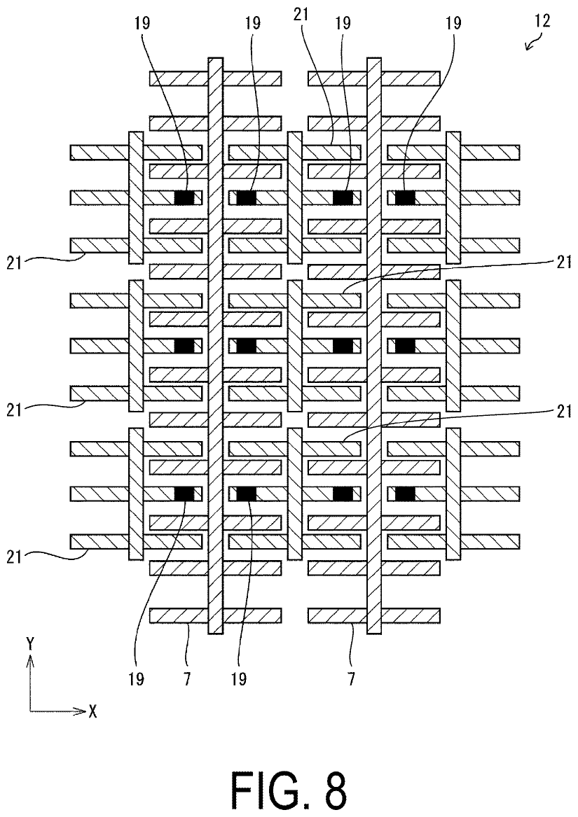

FIG. 8 to FIG. 10 are plan views illustrating steps of forming the transmission electrodes 6 and the reception electrodes 7. Constituent elements similar to the constituent elements described above are given the same reference numerals, and detailed descriptions thereof are not repeated.

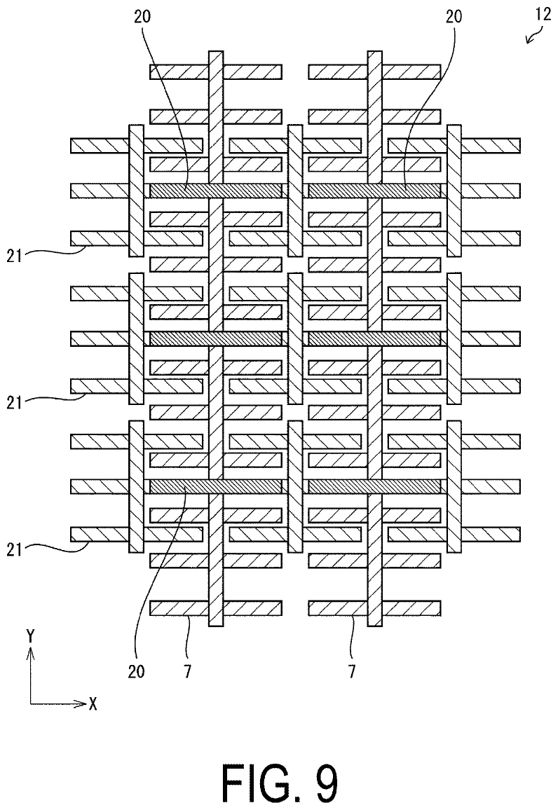

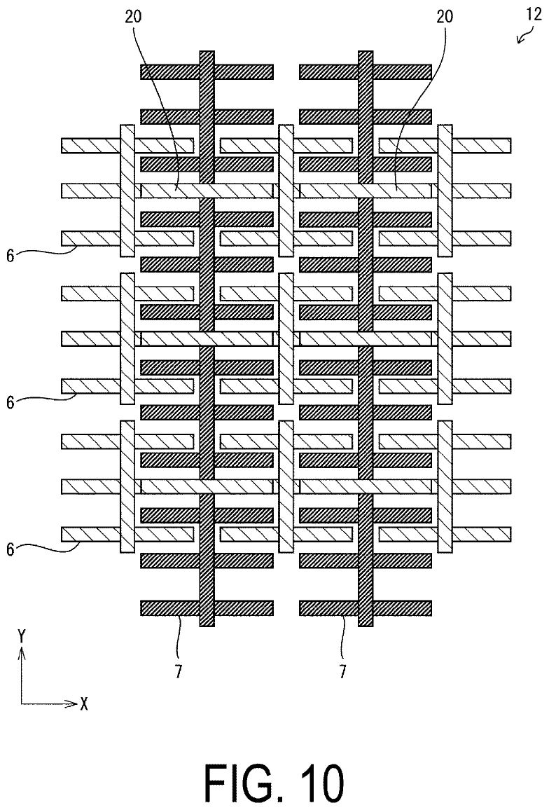

First, a plurality of reception electrodes 7 having a comb shape and extending along the Y direction are formed. Then, as illustrated in FIG. 8, a plurality of partial electrodes 21 having a comb shape are formed in an aligned state with the reception electrodes 7 in the pressure electrode layer 12 so as to be engaged with the comb teeth of the reception electrodes 7. Next, a via hole (contact portion) 19 is formed at each of facing portions of a pair of partial electrodes 21 adjacent to each other with the reception electrode 7 interposed therebetween. Thereafter, as illustrated in FIG. 9, a via hole connecting portion 20 that connects the pair of partial electrodes 21 adjacent to each other with the reception electrode 7 interposed therebetween through the via hole 19 is formed so as to avoid intersecting with the reception electrode 7. Thus, as illustrated in FIG. 10, a plurality of transmission electrodes 6 having a comb shape and extending in the X direction and a plurality of reception electrodes 7 having a comb shape and extending in the Y direction are formed in the same pressure electrode layer 12.

As described above, the transmission electrode 6 extends in the X direction while detouring through the via hole 19 at a position where the transmission electrode 6 intersects with the reception electrode 7 extending in the Y direction.

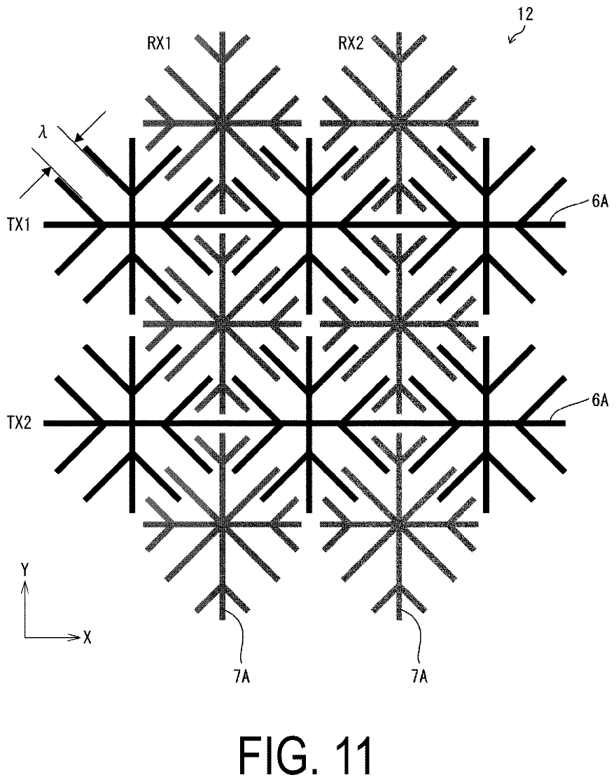

FIG. 11 is a plan view of transmission electrodes 6A and reception electrodes 7A according to a modified example. Constituent elements similar to the constituent elements described above are given the same reference numerals, and detailed descriptions thereof are not repeated.

As illustrated in FIG. 11, the pressure electrode layer 12 may include a plurality of transmission electrodes 6A and a plurality of reception electrodes 7A that are formed in fish bone shapes having a pitch λ less than 500 μm and that are engaged with each other on an identical plane. The example of FIG. 11 illustrates a configuration in which two transmission electrodes 6A having the fish bone shapes and extending in the X direction and two reception electrodes 7A having the fish bone shapes and extending in the Y direction are engaged with each other. In this manner, the reception electrodes 7A are arranged side by side in a direction along the display surface 10 relative to the transmission electrodes 6A.

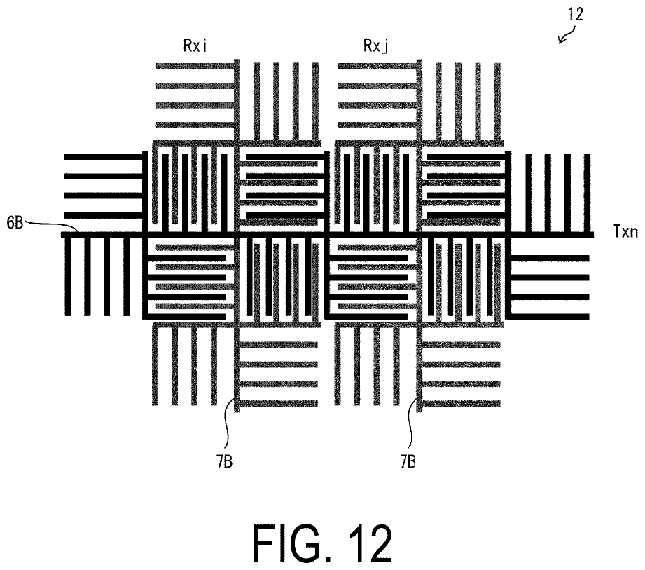

FIG. 12 is a plan view of transmission electrodes 6B and reception electrodes 7B according to another modified example. Constituent elements similar to the constituent elements described above are given the same reference numerals, and detailed descriptions thereof are not repeated.

The pressure electrode layer 12 may include a plurality of transmission electrodes 6B and a plurality of reception electrodes 7B that are formed in an engaging shape. The example of FIG. 12 illustrates a configuration in which one transmission electrode 6B having an engaging shape and extending in the X direction and two reception electrodes 7B having an engaging shape and extending in the Y direction are engaged with each other. In this manner, the reception electrodes 7B are arranged side by side in a direction along the display surface 10 relative to the transmission electrode 6B.

The disclosure is not limited to each of the embodiments described above, and various modifications may be made within the scope of the claims. Embodiments obtained by appropriately combining technical approaches disclosed in each of the different embodiments also fall within the technical scope of the disclosure. Furthermore, novel technical features can be formed by combining the technical approaches disclosed in each of the embodiments.

1. A display device comprising:
a touch sensor configured to detect a touch on a display surface; and
a pressure sensor configured to detect a pressure applied to the display surface,
wherein the pressure sensor includes
a transmission electrode,
a reception electrode arranged side by side in a direction along the display surface relative to the transmission electrode, and
an elastic layer configured to be elastically deformed according to the pressure applied to the display surface, and
the elastic layer has
a thickness equal to or less than 50 μm, and
a longitudinal elastic modulus less than 0.05 MPa.

2. The display device according to claim 1, further comprising:
a light-emitting layer configured to emit light toward the display surface,
wherein the pressure sensor is disposed on a side of the light-emitting layer opposite to the display surface.

3. The display device according to claim 2, further comprising:
a substrate disposed between the light-emitting layer and the pressure sensor, the substrate having elasticity.

4. The display device according to claim 3,
wherein the substrate includes a resin substrate.

5. The display device according to claim 1,
wherein the elastic layer is disposed on a side opposite to the display surface relative to the transmission electrode and the reception electrode.

6. The display device according to claim 1,
wherein the elastic layer includes at least one of an acrylic material, a silicon-based material, or an olefinic material.

7. The display device according to claim 2,
wherein the light-emitting layer includes a self-light-emitting element or a liquid crystal display element.

8. The display device according to claim 7,
wherein the self-light-emitting element includes an OLED.

9. The display device according to claim 2,
wherein the light-emitting layer includes an OLED, and
the display device further includes a ground electrode disposed on a side of the pressure sensor opposite to the display surface, the ground electrode being configured to dissipate heat from the OLED.
